(19) United States
(12) Patent Application Publication
(10) Pub. No.: US 2025/0311643 A1
(43) Pub. Date: Oct. 2, 2025

(54) THERMALLY CONFINED PHASE CHANGE CELLS

(71) Applicant: International Business Machines Corporation, Armonk, NY (US)

(72) Inventors: Ghazi Sarwat Syed, Zurich (CH); Vara Sudananda Prasad Jonnalagadda, Zurich (CH)

(21) Appl. No.: 18/621,020

(22) Filed: Mar. 28, 2024

(51) Int. Cl. H10N 70/20; H10B 63/10; H10N 70/00

(52) U.S. Cl. CPC H10N 70/231; H10N 70/068; H10N 70/841; H10N 70/8613; H10N 70/8828; H10B 63/10

(57) ABSTRACT

A device includes a first electrode, a second electrode, a node between the first electrode and the second electrode, and a thermal confinement structure adjacent the node in which the thermal confinement structure comprises a textured phase change material.

### BACKGROUND

The present invention relates generally to the electrical, electronic and computer arts and, more particularly, to techniques for thermally isolating phase change cells and the like.

Phase change cells can be advantageously incorporated in a wide variety of electronic devices such as switches, memory and storage elements because phase change materials (“PCM”) can reversibly transition from a high resistivity in a non-crystalline state (i.e. RESET) and a low resistivity in a crystalline state (i.e. SET) with the application of current pulses which produce heat. A fast (tens of nanoseconds), high temperature current pulse is used to amorphize the PCM into the high resistance reset sate, while a long (hundreds of nanoseconds to tens of microseconds), medium temperature pulse above the crystallization temperature is used to crystallize the PCM to the low resistance set state.

FIGS. 1A and 1B are a cross-section of aspects of prior art confined and mushroom, respectively, phase change cells. In both cases, the cells 100 include top electrode 110, bottom electrode 120 and a node 130 of phase change material. Adjacent cells are separated by a dielectric material 150 which electrically isolates the cells. The mushroom cell of FIG. 1B also includes a heater connecting the bottom electrode 120 and phase change material 130.

### BRIEF SUMMARY

Principles of the invention provide techniques for a thermal confinement structure adjacent phase change cells. In one aspect, an exemplary semiconductor structure includes a top electrode, a bottom electrode, a node between the top and the bottom electrodes in which the node comprises a phase change material, and a thermal confinement structure in contact with the node in which the thermal confinement structure comprises a dielectric layer and a textured component.

Optionally, the device's textured component comprises a superlattice.

Optionally, the superlattice's Van der Waals gaps are parallel to a current flow of the device

Optionally, the device's top electrode, bottom electrode and the node have the same width.

Optionally, the device's node width is less than a first electrode width.

Optionally, the device's textured component includes alternating layers of a first layer and a second layer in which the first layer contacts the dielectric layer and includes Sb₂Te₃, and the second layer contacts the first layer and the second layer includes GeTe.

Optionally, the device can further include a second top electrode a second bottom electrode and a second node between the second top and the second bottom electrodes in which the thermal confinement structure is in contact with the second node and wherein the dielectric layer is u-shaped.

In another aspect, an exemplary device includes a top electrode, a bottom electrode, a node between the top and the bottom electrodes wherein the node includes a phase change material, a thermal confinement structure in contact with and overlying the node in which the thermal confinement structure comprises a first layer and a second layer.

Optionally, the device's thermal confinement structure comprises a superlattice.

Optionally, the superlattice's Van der Waals gaps are perpendicular to a current flow of the device.

Optionally, the top electrode and the node have the same width which is greater than the width of a bottom electrode.

In a further aspect, an exemplary device includes a first phase change cell, a second phase change cell and a thermal confinement structure between the first and the second phase change cells in which the thermal confinement structure includes a dielectric layer and a textured phase change material.

Optionally, the dielectric layer conforms to a bottom surface, a first phase change cell sidewall and a second phase change cell sidewall.

Optionally, an entire sidewall of each of first and second phase change cells are straight and parallel to each other.

Optionally, the first and second phase change cells include a top electrode, a bottom electrode, and a node between the top and the bottom electrodes and in which a node width is less than an electrode width.

In yet another aspect, an exemplary device including a first electrode, a second electrode, a node between the first electrode and the second electrode; and a thermal confinement structure adjacent the node in which the thermal confinement structure comprises a textured phase change material.

Optionally, the device's thermal confinement structure further comprises a dielectric material in contact with the node and in which a portion of the textured phase change material is disposed parallel to a device current direction. The addition of the dielectric layer further enhances heat resistance.

Optionally, a second portion of the textured phase change material is disposed perpendicular to a device current direction.

Optionally, the first electrode and the node do not have a common width.

Optionally, the device's thermal confinement structure is located between the node and the first electrode, and the thermal confinement structure further includes a seed layer in contact with the node, and at least a portion of the textured phase change material is disposed perpendicular to a device current direction.

In still a further aspect, an exemplary method of forming a device includes forming a first electrode, forming a second electrode, forming a node between the first electrode and the second electrode, and forming a thermal confinement structure adjacent the node in which the thermal confinement structure comprises a textured phase change material.

Optionally, the thermal confinement structure further comprises a dielectric material in contact with the node and wherein a portion of the textured phase change material is disposed parallel to a device current direction.

Optionally, a portion of the textured phase change material is disposed perpendicular to a device current direction.

Optionally, the first electrode and the node do not have a common width.

Optionally, the thermal confinement structure is located between the node and the first electrode in which the thermal confinement structure further includes a seed layer in contact with the node, and at least a portion of the textured phase change material is disposed perpendicular to a programming current direction.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
Allow reduction of programming current by reducing heat loss;
Allow improved reliability by reducing heat loss, by limiting thermal crosstalk between neighboring devices;
Allows for reduction in cell size and thus aids in high integration density;
Allows easy manufacturability in the back-end-of-the-line; and
Allows an increase in device cyclability by reductions in electrical power requirement for programming.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1A is a cross-section depicting aspects of a prior art confined phase change cell;

FIG. 1B is a cross-section depicting aspects of a prior art mushroom phase change cell;

FIG. 2 is a cross-section depicting a confined phase change cell, according to aspects of the invention;

FIG. 3 is a cross-section depicting further details of confined phase change cell, according to aspects of the invention;

FIG. 4 is a cross-section depicting another configuration of confined phase change cell, according to aspects of the invention;

FIG. 5 is a cross-section depicting a mushroom configuration of a phase change cell, according to aspects of the invention;

FIG. 6 is a lumped circuit model illustrating the various resistors that make a thermal circuit for the prior art FIG. 1A;

FIG. 7 is a lumped circuit model illustrating the various resistors that make a thermal circuit for the aspect of the invention depicted in FIG. 2; and

FIG. 8 is a lumped circuit model illustrating the various resistors that make a thermal circuit of FIG. 4.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

In one aspect, an exemplary device includes a top electrode 110, a bottom electrode 120, a node 130 between the top and the bottom electrodes in which the node comprises a phase change material, and a thermal confinement structure 155 in contact with the node in which the thermal confinement structure comprises a dielectric layer 152 and a textured component 170. When a thermal confinement structure is not in place, heat loss to the surrounding medium (e.g. dielectric material 150) can be as high as 90% and is a major mechanism limiting the programming efficiency in phase change memory devices. By using a thermal confinement structure, heat is retained in the cell which increases programming efficiency.

Optionally, the device's textured component 170 comprises a superlattice. A benefit of using a superlattice is that it is a material with reduced thermal conductivity values and smaller temperature sensitivity compared to dielectric materials 150 (e.g. silicon dioxide or silicon nitride). Thus, a material, such as a superlattice which can have fairly consistent low thermal conductivity value over a range of temperatures can aid thermal confinement.

Optionally, the superlattice's Van der Waals gaps (75 are parallel to a current flow of the device. A key benefit of van der Waals gaps is to enable thermal confinement of the heat generated from Joule heating in the device. Thus, the effective thermal resistance of the device is increased.

Optionally, the device's top electrode 110, bottom electrode 120 and the node 130 have the same width. A benefit of common width among cell 100 components is that additional thermal boundary resistances and the low thermal conductivity of the textured component 170 reduces the heat flux between the devices which in turn enables a reduction in thermal crosstalk between neighboring devices. Optionally, the device's node width 130w is less than a first electrode width 110w. A benefit of narrower node width compared to electrode width is that a seam or void can be created when trying to fill the adjacent space with textured material. This seam or void will reduce the thermal conductance further.

Optionally, the device's textured component includes alternating layers of a first layer and a second layer in which the first layer contacts the dielectric layer and includes Sb₂Te 3, and the second layer contacts the first layer and the second layer includes GeTe. A technical benefit of the recited alternation layers is low thermal conductivity and manufacturability. The latter arises from the back-end-of-the-line compatibility of the structure and materials.

Optionally, the device can further include a second top electrode a second bottom electrode and a second node between the second top and the second bottom electrodes in which the thermal confinement structure 155 is in contact with the second node and wherein the dielectric layer 152 is u-shaped. A technical benefit is an adjacent cell (e.g. the second set of electrodes and node) is shielded from heat produced by the programmed cell by the intervening thermal confinement structure 155. If the thermal confinement structure 155 was absent, heat loss would result in write-disturbance in the adjacent cell. In particular, amorphous marks in the adjacent cells would decrease from thermal cross-talk induced crystallization when the first cell is programmed. Heat induced cross-talk of cells adjacent to programmed cells is a major factor limiting the scalability of the phase change memory technology.

In another aspect, an exemplary device includes a top electrode 110, a bottom electrode 120, a node 130 between the top and the bottom electrodes wherein the node includes a phase change material, a thermal confinement structure 155 in contact with and overlying the node 130 in which the thermal confinement structure 155 comprises a first layer 171 and a second layer 172. A technical benefit of the mushroom cell with a dual layer thermal confinement structure 155 is textured component 170 can be extended as a top electrode 110 for the node 130. Thus, while electrically conducting, the multilayered textured component 170 would provide thermal insulation from the metallic top electrode 110.

Optionally, the device's thermal confinement structure comprises a superlattice. A benefit of using a superlattice is that it is a material with reduced thermal conductivity values and smaller temperature sensitivity compared to dielectric materials 150 (e.g. silicon dioxide or silicon nitride). Thus, a material, such as a superlattice which can have fairly consistent low thermal conductivity value over a range of temperatures can aid thermal confinement.

Optionally, the superlattice's Van der Waals gaps 175 are perpendicular to a current flow of the device. A benefit of gaps perpendicular to the current flow is enhanced heat capacity.

Optionally, the top electrode 100 and the node 130 have the same width which is greater than the width of a bottom electrode 120. A benefit of a narrow bottom 120 electrode is that it acts as a heater which accelerates programming of the cell.

In a further aspect, an exemplary device includes a first phase change cell, a second phase change cell and a thermal confinement structure 155 between the first and the second phase change cells in which the thermal confinement structure 155 includes a dielectric layer 152 and a textured phase change material. A technical benefit is a second cell is shielded from heat produced by the programmed cell (first cell) by the intervening thermal confinement structure 155. If the thermal confinement structure 155 was absent, heat loss would result in write-disturbance in the adjacent cell. In particular, amorphous marks in the adjacent cells would decrease from thermal cross-talk induced crystallization when the first cell is programmed. Heat induced cross-talk between cells adjacent to programmed cells is a major factor limiting the scalability of the phase change memory technology.

Optionally, the dielectric layer 152 conforms to a bottom surface, a first phase change cell sidewall and a second phase change cell sidewall. A benefit of the conformal dielectric layer is manufacturability and increased thermal resistance.

Optionally, an entire sidewall of each of first and second phase change cells are straight and parallel to each other. A benefit of straight and parallel cell sidewalls is that additional thermal boundary resistances and the low thermal conductivity of the textured phase change material reduces the heat flux between the devices.

Optionally, the first and second phase change cells include a top electrode, a bottom electrode, and a node between the top and the bottom electrodes and in which a node width is less than an electrode width. Such a configuration can often advantageously create a seam or void which will reduce the thermal conductance further.

In yet another aspect, an exemplary device including a first electrode 110, a second electrode 120, a node 130 between the first electrode and the second electrode; and a thermal confinement structure 155 adjacent the node 130 in which the thermal confinement structure 155 comprises a textured phase change material. When a thermal confinement structure is not in place, heat loss to the surrounding medium (e.g. dielectric material 150) can be as high as 90% and is a major mechanism limiting the programming efficiency in phase change memory devices. By using a thermal confinement structure, heat is retained in the cell which increases programming efficiency.

Optionally, the device's thermal confinement structure 155 further comprises a dielectric material 152 in contact with the node 130 and wherein a portion of the textured phase change material is disposed parallel to a device current direction. The addition of the dielectric layer 152 further enhances heat resistance. A benefit of textured phase change material disposed parallel to current flow is ease of manufacturing. Optionally, a second portion of the textured phase change material is disposed perpendicular to a device current direction. A benefit of textured phase change material disposed perpendicular to current flow is enhanced heat capacity.

Optionally, the first electrode and the node do not have a common width. A benefit of narrower node width compared to electrode width is that a seam or void can be created when trying to fill the adjacent space with textured phase change material. This seam or void will reduce the thermal conductance further.

Optionally, the device's thermal confinement structure 155 is located between the node 130 and the first electrode 110, and the thermal confinement structure 15 further includes a seed layer in contact with the node 130, and at least a portion of the textured phase change material is disposed perpendicular to a device current direction. A technical benefit of the configuration is the textured phase change material can be extended as a top electrode 110 for the node 130. Thus, while electrically conducting, the textured phase change material provides thermal insulation from the metallic top electrode 110.

In still a further aspect, an exemplary method of forming a device includes forming a first electrode 110, forming a second electrode 120, forming a node 130 between the first electrode 110 and the second electrode 120, and forming a thermal confinement structure 155 adjacent the node 130 in which the thermal confinement structure 155 comprises a textured phase change material. When a thermal confinement structure is not in place, heat loss to the surrounding medium (e.g. dielectric material 150) can be as high as 90% and is a major mechanism limiting the programming efficiency in phase change memory devices. By using a thermal confinement structure, heat is retained in the cell which increases programming efficiency.

Optionally, the thermal confinement structure 155 further comprises a dielectric material 152 in contact with the node 130 and wherein a portion of the textured phase change material is disposed parallel to a device current direction. A benefit of textured phase change material disposed parallel to current flow is ease of manufacturing.

Optionally, a portion of the textured phase change material is disposed perpendicular to a device current direction. A benefit of textured phase change material disposed perpendicular to current flow is enhanced heat capacity_

Optionally, the first electrode and the node do not have a common width. A benefit of narrower node width compared to electrode width is that a seam or void can be created when trying to fill the adjacent space with textured material. This seam or void will reduce the thermal conductance further.

Optionally, the thermal confinement structure 155 is located between the node 130 and the first electrode in which the thermal confinement structure 155 further includes a seed layer in contact with the node 130, and at least a portion of the textured phase change material is disposed perpendicular to a programming current direction. A technical benefit of the configuration is the thermal confinement structure 155 can be extended as a first electrode for the node 130. Thus, while electrically conducting, the thermal confinement structure 155 provides thermal insulation from the metallic first electrode.

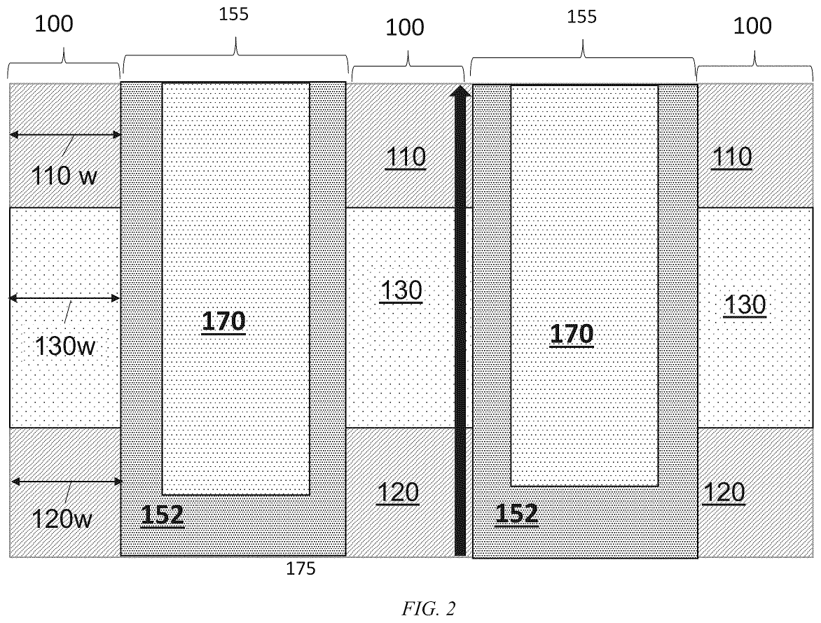

Referring to an embodiment of a device depicted in FIG. 2, three cells 100 are separated by a two thermal confinement structures 155. The cells include a bottom electrode 120, a node 130 of phase change material and a top electrode 110. The node width 130w, bottom electrode width 120w and the top electrode width 110w can be equal within normal process tolerances. The electrodes can be TiN or any suitable conductor or combination of conductors. One or more of the electrodes can, optionally, also function as a heater. Or an additional heater, not shown, can be between one or both of the electrodes and the node 130. The heater can be TiN or any suitable material or combination. The current in the cells 100 flows vertically (see bold arrow of FIG. 2).

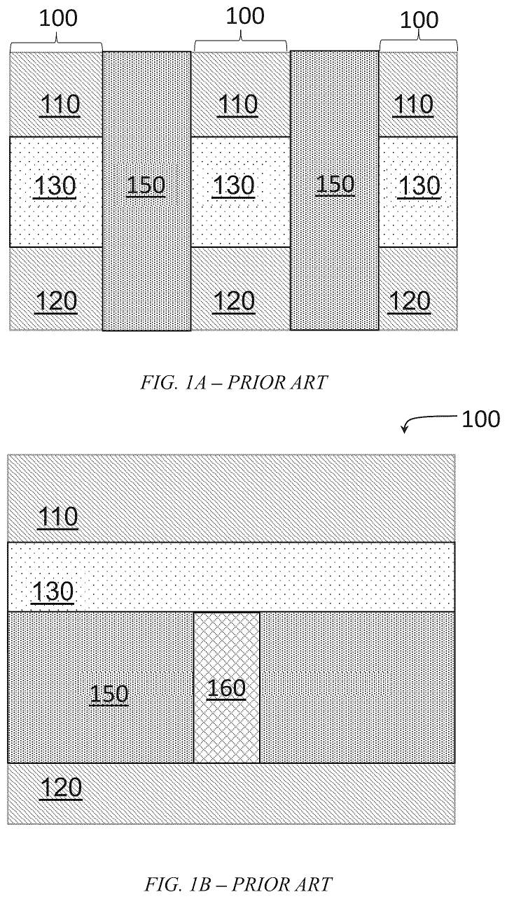

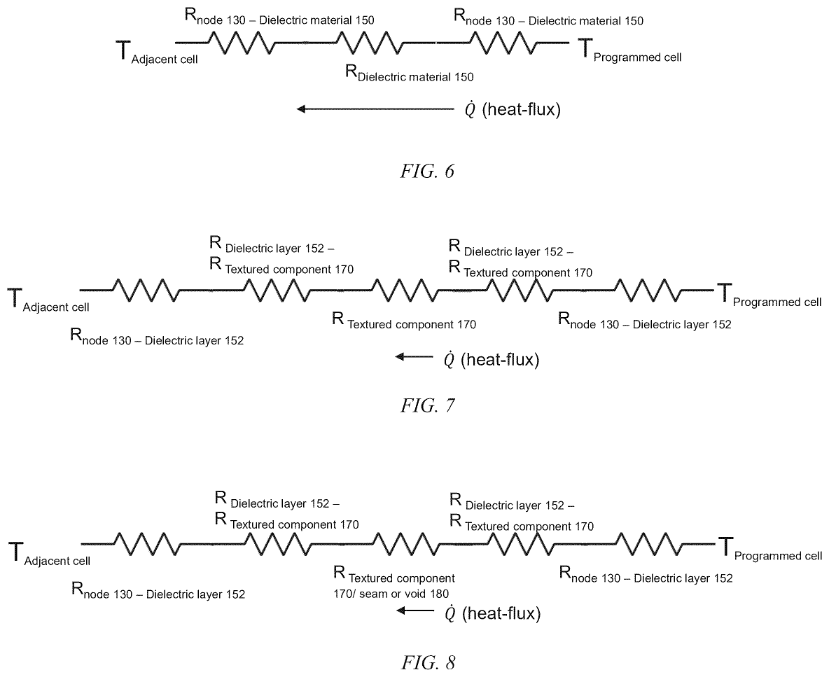

With continuing reference to FIG. 2, the thermal confinement structure 155 can include a dielectric layer 152, and a textured component 170. A textured component 170, as opposed to an untextured component, includes layered materials with intervening Van der Waals gaps. An untextured component is one that lacks Van der Waals (herein, “VDW”) gaps. An untextured component, in addition to lacking VWG, can have a randomly oriented crystal structure. While the thermal confinement structure 155 always includes a textured component 170, the phase change material of node 130 can be either textured or untextured. Advantageously, the thermal confinement structure's additional thermal boundary resistances and the low thermal conductivity of the textured component 170 is expected to reduce the heat flux between adjacent cells. For example, FIG. 6 is a lumped circuit model illustrating the various resistors that make a thermal circuit for the prior art FIG. 1A.

FIG. 7 is a lumped circuit model illustrating the various resistors that make a thermal circuit for the aspect of the invention depicted in FIG. 2.

The FIG. 2 model has greater thermal resistance to the prior art FIG. 1A not only because the existence of the texture material creates more interfaces, but also because the resistance of the texture component 170 is greater than the resistance of the dielectric material 150 of the prior art. With thermal engineering of the dielectric layer 152, melting in the textured component 170 can be negated. However, the textured component 170 can also be designed to amorphize if melt quenched, such that thermal confinement effect can remain unchanged, if not improved.

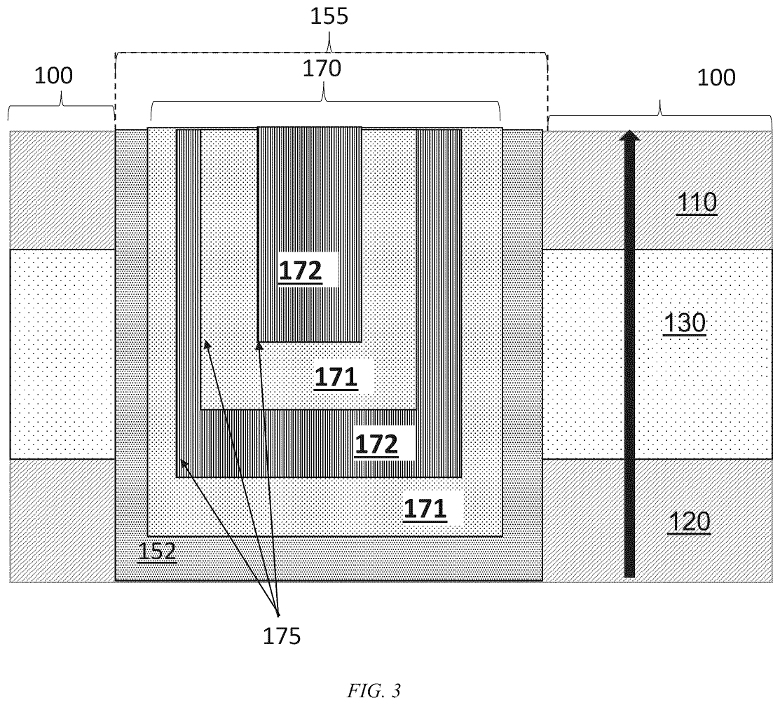

Referring to FIG. 3, an aspect of the textured component 170 of the thermal confinement structure 155 is further described. The textured component 170 can include at least two layers, a first layer 171 adjacent the dielectric layer 152 and a second layer 172 adjacent the first layer 171. Being a textured material, VDW gaps 175 appear between the first and second layers. This first layer 171, second layer 172 with intervening VDW gaps 175 can be repeated (in the FIG. 3 example, it is repeated twice). The first and second layers can be the same material (homoepitaxial) or can be different materials (heteroepitaxial). The first layer 171 can be a seed layer. The textured component 170 can be a superlattice. The textured component 170 can include chalcogenide materials. In one embodiment, the first layer 171 is Sb₂Te₃ and the second layer 172 is GeTe. Other materials suitable as textured or untextured materials are described later.

Still referring to FIG. 3, the dielectric layer 152, the first layer 171 and second layer 172 can form a U-shape in an opening between cells. Due to the aspect ratio of the thermal confinement structure 155 and the largely conformal nature of the deposited films, the VDW gaps 175 can be mostly in a direction parallel to the current flow (see bold arrow of FIG. 3).

While FIG. 3 depicts the confined cell in which the layers of thermal confinement structure 155 fill a spaced between cells, it is also possible that the layers cover the top of the cells, too, to provide a top encapsulation. Furthermore, the layers of thermal confinement structure 155 could be deposited prior to cell film deposition and formation to further encapsulate the cells 100 on the bottom, too.

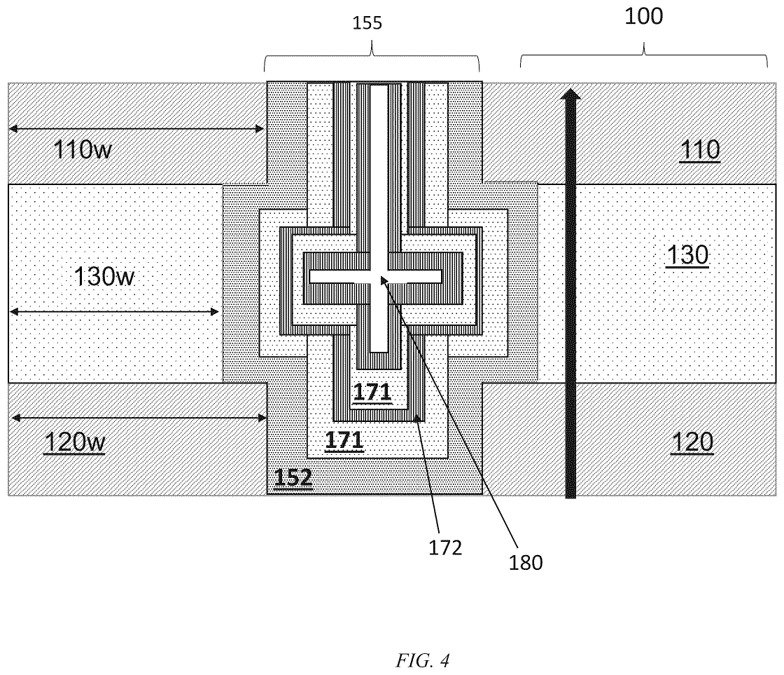

With reference to FIG. 4, an aspect of the confined cell has different electrode and node widths node widths. In the aspect of FIG. 4 bottom electrode width 120w and the top electrode width 110w can be equal within normal process tolerances while node width 130w is less than the bottom electrode width 120w and the top electrode width 110w. As a result, the thermal confinements structure 155 located between cells can have a wider width at an area adjacent the node 130 and a narrower width at areas adjacent the bottom electrode 120 and top electrode 110. The difference in widths can be achieved as a result of lithographic patterning or can be created by exploiting the selectivity in the sidewall etch rates between the electrode and the node. Due to the uneven sidewall of the cell 100, a seam or void 180 can form. The seam or void further increases the thermal boundary resistances. For example, FIG. 8 is a lumped circuit model illustrating the various resistors that make a thermal circuit of FIG. 4.

Here, the resistance of the combined textured component 170 and seam or void 180 is greater than the resistance of the textured component 170 which in turn is greater than the resistance of the dielectric layer 152 which results in a lower heat flux compared to the prior art's FIG. 1A's model previously described.

While not shown in FIG. 4, it should be understood that VDW gaps appear at the interfaces between the first layer 171 and the second layer 172. The VDW gaps will largely be parallel to the direction of current flow (bold arrow) of the cell 100.

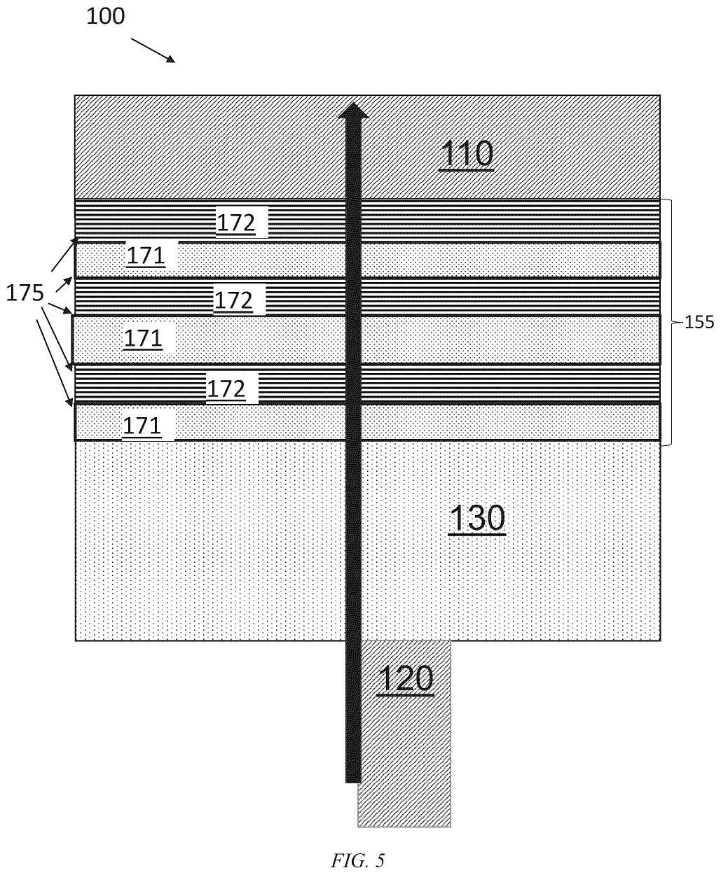

With reference to FIG. 5, an aspect of a mushroom cell 100 is depicted having a bottom electrode 120, node 130, thermal confinement structure 155 and top electrode 110. The materials of the bottom electrode 120, node 130, thermal confinement structure 155 and top electrode 110 can be as previously described with the exception that the thermal confinement structure 155 while having first layer 171 and second layer 172, it can lack a dielectric layer 152 (as shown in FIG. 5). Because the thermal confinement structure 155 is formed on horizontal surface of the node 130, the VDW gaps 175 form horizontally or stated another way, the VDW gaps 175 are perpendicular to the direction of the cell's current flow as indicated by the bold vertical arrow of FIG. 5.

The thermal confinement structure 155 can be grown by depositing a seed layer (not shown) between the node 130 and the first layer 171, or through indirect seeding where a conductive layer like amorphous carbon provides templating of layers such as Sb₂Te₃, which then act as seeding layer. In another extension, the thermal confinement structure 155 can be realized using the node 130 (e.g. untextured phase change material) as the seeding substrate. In one embodiment, to build this mushroom cell 100 the node 130 (e.g. untextured phase change material) can be deposited at room temperature, resulting in an amorphous and highly resistive state. The node's surface is charged using an ion beam (e.g., Ar) and a seed layer is deposited at room temperature. The temperature is raised to ˜200C to deposit the textured component 170.

Other materials suitable as textured or untextured materials are phase change materials which can include Ge2Sb2Te5, Ge-rich GeSbTe (GST) chalcognide alloys, carbon-doped GeSbTe (GST), N-doped GST, impurity doped phase change materials such as Ti-doped Sb2Te3 and Sc-doped Sb2Te3. SiSbTe (SST). GaSbTe, GeBi,Te. Phase change materials include chalcogenide compositions such as an alloy including at least two of the elements within the indium(In)-antimony(Sb)-tellurium(Te) (IST) alloy system, e.g., In2Sb2Te5, In1Sb2Te4, In1Sb4Te7, etc., an alloy including at least two of the elements within the germanium(Ge)-antimony(Sb)-tellurium(Te) (GST) alloy system, e.g., Ge8Sb5Te8, Ge2Sb2Te5, Ge1Sb2Te4, Ge1Sb4Te7, Ge4Sb4Te7, etc., among other chalcogenide alloy systems. The hyphenated chemical composition notation, as used herein, indicates the elements included in a particular mixture or compound, and is intended to represent all stoichiometries involving the indicated elements. Other chalcogenide alloy systems that can be used in phase change storage nodes include Ge—Te, In—Se, Sb—Te, Ga—Sb, In—Sb, As—Te, Al—Te, In—Ge—Te, Ge—Sb—Te, Te—Ge—As, In—Sb—Te, Te Sn—Se, Ge—Se—Ga, Bi—Se—Sb, Ga—Se—Te, Sn—Sb—Te, In—Sb—Ge, Te—Ge—Sb—S, Te—Ge—Sn—O, Te—Ge—Sn—Au, Pd—Te—Ge—Sn, In—Se—Ti—Co, Ge—Sb—Te—Pd, Ge—Sb—Te—Co, Sb—Te—Bi—Se, Ag—In—Sb—Te, Ge—Sb—Se—Te, Ge—Sn—Sb—Te, Ge—Te—Sn—Ni, Ge—Te—Sn—Pd, and Ge—Te—Sn—Pt, for example. In addition alternating layers of chalcogenide material and a second non-chalcogenide material such as doped/undoped metal nitride, doped/undoped carbon can form a superlattice structure. Metal nitrides may include TiₓTe_{y}, TaₓTe_{y} compositions.

Superlattices can include phase change materials arranged in superlattice (SL) stacks with alternating layers of one or more of the materials listed above.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A device comprising:
a top electrode;
a bottom electrode;
a node between the top and the bottom electrodes wherein the node comprises a phase change material;
a thermal confinement structure in contact with the node; and
wherein the thermal confinement structure comprises a dielectric layer and a textured component.

2. The device of claim 1, wherein the textured component comprises a superlattice.

3. The device of claim 2, wherein a Van der Waals gap of the superlattice is parallel to a current flow of the device.

4. The device of claim 1, wherein the top electrode, bottom electrode and the node have the same width.

5. The device of claim 1, wherein a node width is less than a first electrode width.

6. The device of claim 1 wherein the textured component comprises alternating layers of a first layer and a second layer;
wherein the first layer contacts the dielectric layer and wherein the first layer comprises Sb₂Te₃, and
wherein the second layer contacts the first layer and wherein the second layer comprises comprising GeTe.

7. The device of claim 1 further comprising:
a second top electrode;
a second bottom electrode; and
a second node between the second top and the second bottom electrodes;
wherein the thermal confinement structure is in contact with the second node and wherein the dielectric layer is u-shaped.

8. A device comprising:
a top electrode;
a bottom electrode;
a node between the top and the bottom electrodes wherein the node comprises a phase change material;
a thermal confinement structure in contact with and overlying the node; and
wherein the thermal confinement structure comprises a first layer and a second layer.

9. The device of claim 8, wherein the thermal confinement structure comprises a superlattice.

10. The device of claim 9, wherein a Van der Waals gap of the superlattice is perpendicular to a current flow of the device.

11. The device of claim 8, wherein the top electrode the node have the same width which is greater than a bottom electrode width.

12. A device comprising:
a first phase change cell;
a second phase change cell; and
a thermal confinement structure between the first and the second phase change cells;
wherein the thermal confinement structure comprises a dielectric layer and a textured phase change material.

13. The device of claim 12, wherein the dielectric layer conforms to a bottom surface, a first phase change cell sidewall and a second phase change cell sidewall.

14. The device of claim 13, wherein an entire sidewall of each of first and second phase change cells are straight and parallel to each other.

15. The device of claim 13 wherein in each of the first and second phase change cells comprises a top electrode, a bottom electrode, and a node between the top and the bottom electrodes; and
wherein a node width is less than an electrode width.

16. A device comprising:
a first electrode 110;
a second electrode 120;
a node 130 between the first electrode and the second electrode; and
a thermal confinement structure 155 adjacent the node;
wherein the thermal confinement structure comprises a textured phase change material.

17. The device of claim 16 wherein the thermal confinement structure further comprises a dielectric material in contact with the node and wherein a portion of the textured phase change material is disposed parallel to a device current direction.

18. The device of claim 17 wherein a second portion of the textured phase change material is disposed perpendicular to a device current direction.

19. The device of claim 17 wherein the first electrode and the node do not have a common width.

20. The device of claim 16, wherein:
the thermal confinement structure is located between the node and the first electrode;
the thermal confinement structure further comprises a seed layer in contact with the node; and
at least a portion of the textured phase change material is disposed perpendicular to a device current direction.

21. A method of making a device comprising:
forming a first electrode;
forming a second electrode;
forming a node between the first electrode and the second electrode; and
forming a thermal confinement structure adjacent the node;
wherein the thermal confinement structure comprises a textured phase change material.

22. The method of claim 21, wherein the thermal confinement structure further comprises a dielectric material in contact with the node and wherein a portion of the textured phase change material is disposed parallel to a device current direction.

23. The method of claim 21, wherein a portion of the textured phase change material is disposed perpendicular to a device current direction.

24. The method of claim 22, wherein the first electrode and the node do not have a common width.

25. The method of claim 21, wherein:
the thermal confinement structure is located between the node and the first electrode;
the thermal confinement structure further comprises a seed layer in contact with the node; and
at least a portion of the textured phase change material is disposed perpendicular to a programming current direction.
